(19) United States
(12) Patent Application Publication
(10) Pub. No.: US 2016/0190045 A1
(43) Pub. Date: Jun. 30, 2016

(54) SEMICONDUCTOR DEVICE AND METHOD OF MAKING THE SAME

(71) Applicant: ROHM CO., LTD., Kyoto-shi (JP)

(72) Inventors: Kenji FUJII, Kyoto-shi (JP); Mamoru YAMAGAMI, Kyoto-shi (JP)

(21) Appl. No.: 14/971,313

(22) Filed: Dec. 16, 2015

(30) Foreign Application Priority Data
Dec. 24, 2014 (JP) 2014-260257
Nov. 26, 2015 (JP) 2015-230357

(51) Int. Cl. H01L 23/495; H01L 21/48; H01L 21/56; H01L 23/31

(52) U.S. Cl. CPC H01L 23/49527; H01L 23/49541; H01L 23/49568; H01L 23/49582; H01L 23/3114; H01L 21/4825; H01L 21/565

(57) ABSTRACT

A semiconductor device includes: a semiconductor element having a functional surface formed with a functional circuit and a reverse surface opposite to the functional surface; an electroconductive support member supporting the semiconductor element and electrically connected to the semiconductor element; and a resin package covering the semiconductor element and at least a part of the electroconductive support member. The semiconductor element is provided with an electrode including a projection on the functional surface and with a reinforcing layer formed on the functional surface. The semiconductor device further includes a solid-state welded portion formed by solid state welding of at least a part of the projection of the electrode and at least a part of the electroconductive support member.

### BACKGROUND OF THE INVENTION

1. Field of the Invention

The present disclosure relates to a semiconductor device and a method of making a semiconductor device.

2. Description of Related Art

A semiconductor device incorporating a semiconductor element employs an electroconductive support member for forming a conduction path to the semiconductor element while supporting the semiconductor element. As disclosed in e.g. JP-A-2014-7363, a lead made of a metal is used as the electroconductive support member in such a semiconductor device. A plurality of wires made of e.g. Au are used as a means for electrically connecting the semiconductor element and the lead.

Making such a semiconductor device involves a process of bonding wires. The bonding process is performed successively with respect to each of the wires and cannot be performed collectively with respect to the plurality of wires. This hinders the improvement of the manufacturing efficiency of a semiconductor device. Moreover, since wires are relatively thin, they may be accidentally cut or detached in the process of making or using the semiconductor device. Further, in the case where a heat dissipation member is to be attached to a semiconductor element, a bonding material is currently used to bond the semiconductor element and the heat dissipation member.

### SUMMARY OF THE INVENTION

The present disclosure has been proposed under the above-described circumstances and provides a semiconductor device that enables an improvement in the manufacturing efficiency as well as an enhancement in strength and reliability of bonding between a semiconductor element and an electroconductive support member or a heat dissipation member. The present disclosure further provides a method of making such a semiconductor device.

A semiconductor device provided according to a first aspect of the present invention includes: a semiconductor element including a functional surface formed with a functional circuit and a reverse surface opposite to the functional surface; an electroconductive support member supporting the semiconductor element and electrically connected to the semiconductor element; and a resin package covering the semiconductor element and at least a part of the electroconductive support member. The semiconductor element is provided with an electrode including a projection formed on the functional surface and a reinforcing layer formed on the functional surface. The semiconductor device further includes a first solid-state welded portion formed by solid state welding of at least a part of the projection of the electrode and at least a part of the electroconductive support member.

A method of making a semiconductor device provided according to a second aspect of the present invention includes: a step of forming an electroconductive support member of a metal on a sacrificial member; a solid state welding step of bonding, by solid state welding, the electroconductive support member and an electrode, the electrode being formed on a functional surface of a semiconductor element and including a projection; and a step of removing the sacrificial member.

Other features and advantages of the present invention will become apparent from the detailed description given below with reference to the accompanying drawings.

### BRIEF DESCRIPTION OF THE DRAWINGS

FIG. 1 is a plan view shoeing a semiconductor device according to a first embodiment of the present disclosure;

FIG. 2 is a bottom view showing the semiconductor device of FIG. 1;

FIG. 3 is a front view showing the semiconductor device of FIG. 1;

FIG. 4 is a side view showing the semiconductor device of FIG. 1;

FIG. 5 is a sectional view taken along lines V-V in FIG. 1;

FIG. 6 is an enlarged sectional view showing a main section of the semiconductor device of FIG. 1;

FIG. 7 is an enlarged sectional view showing an example of a method of making the semiconductor device of FIG. 1;

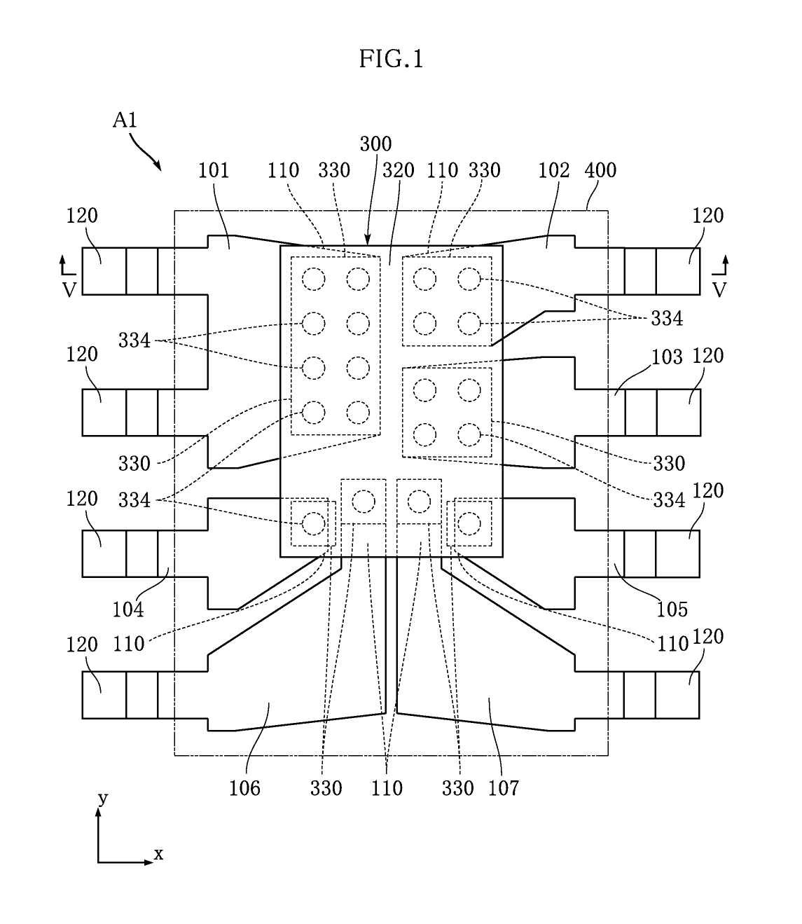

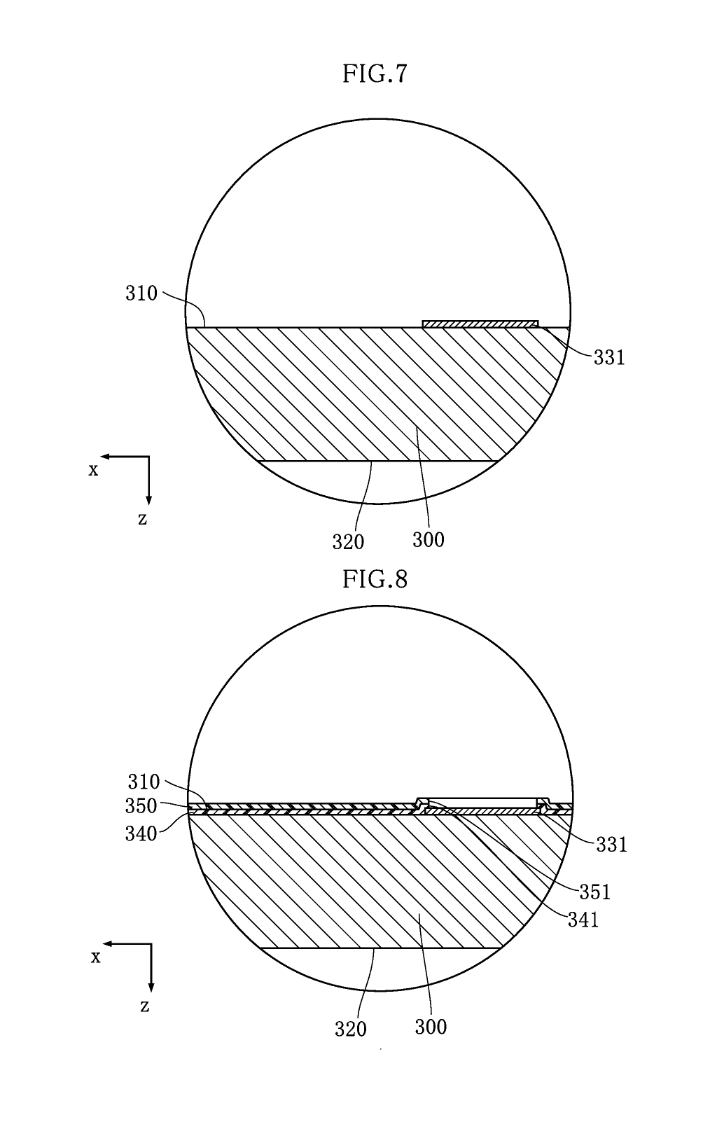

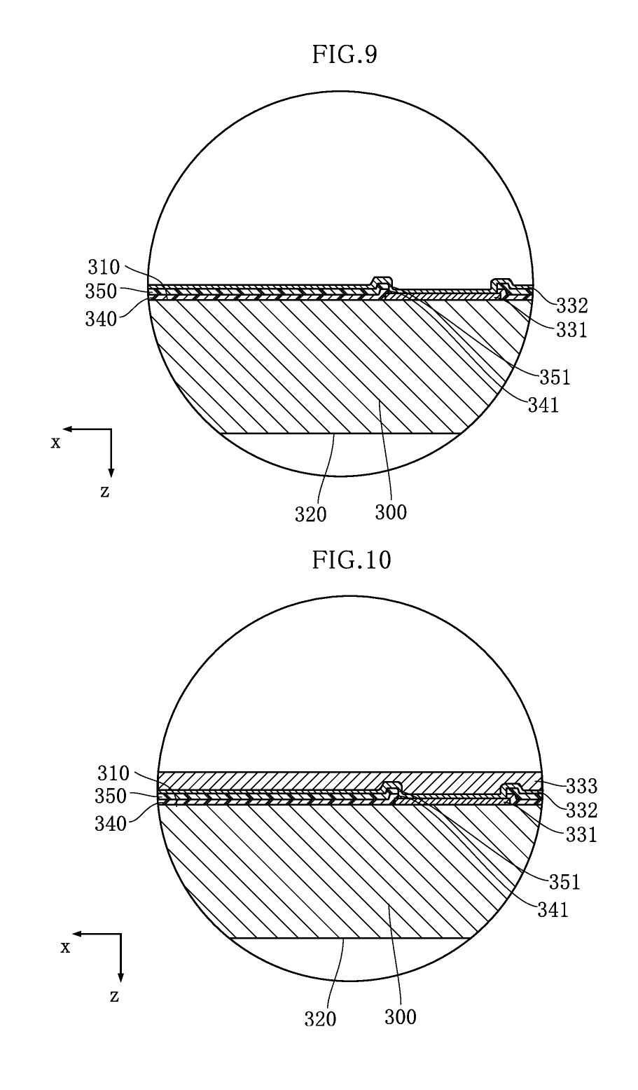

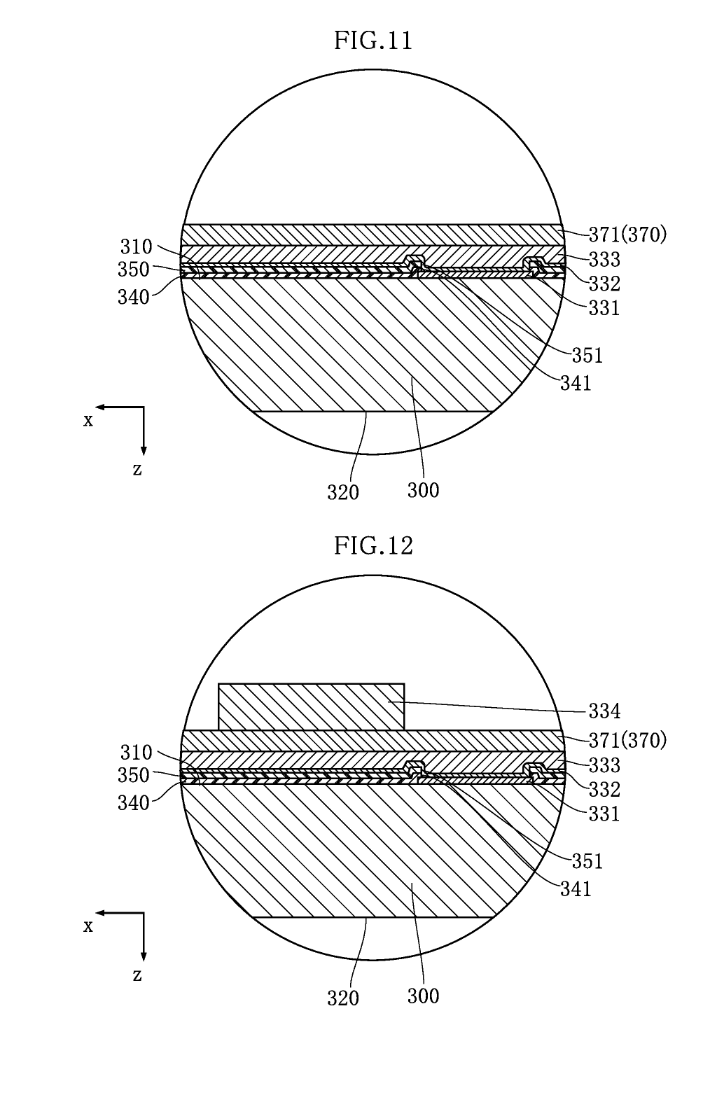

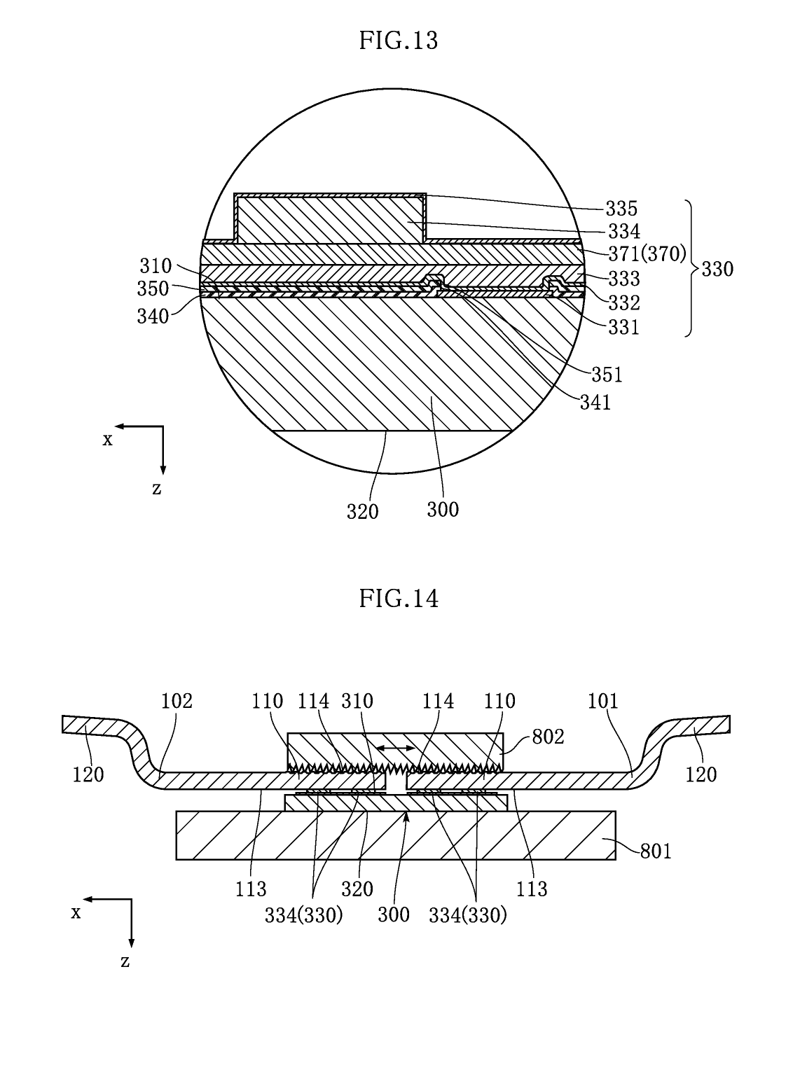

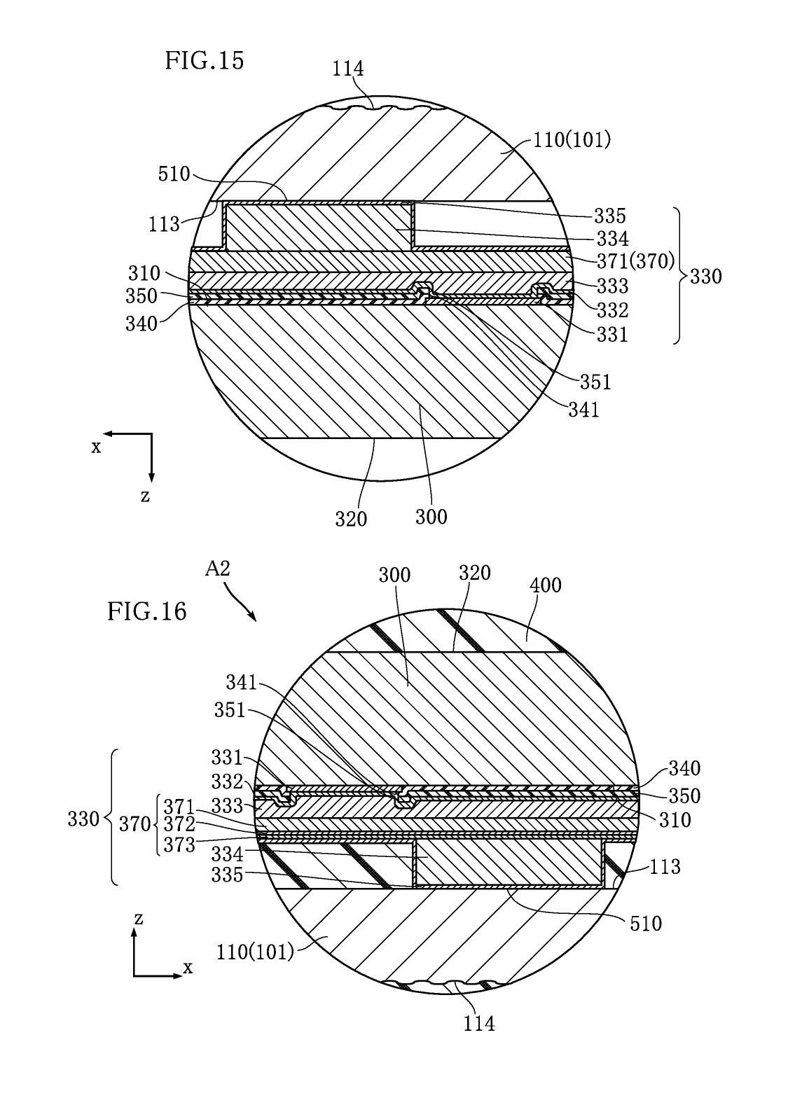

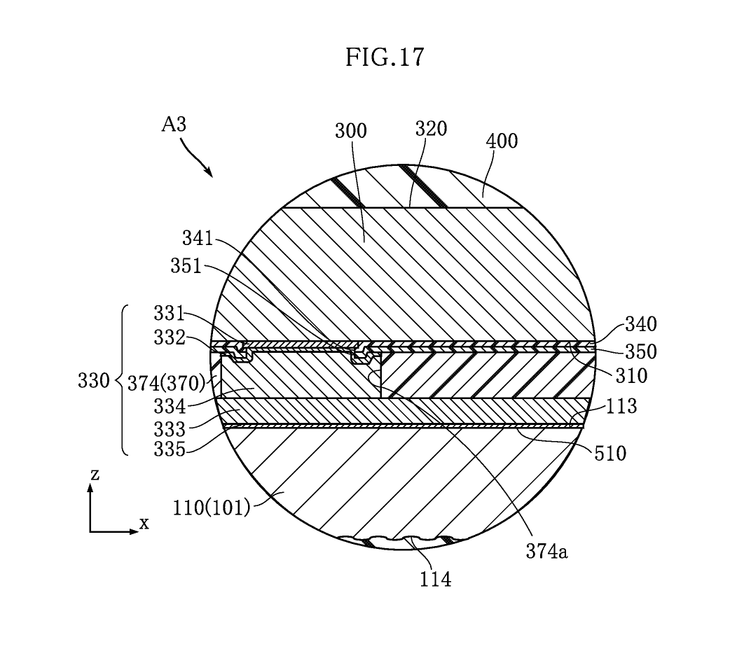

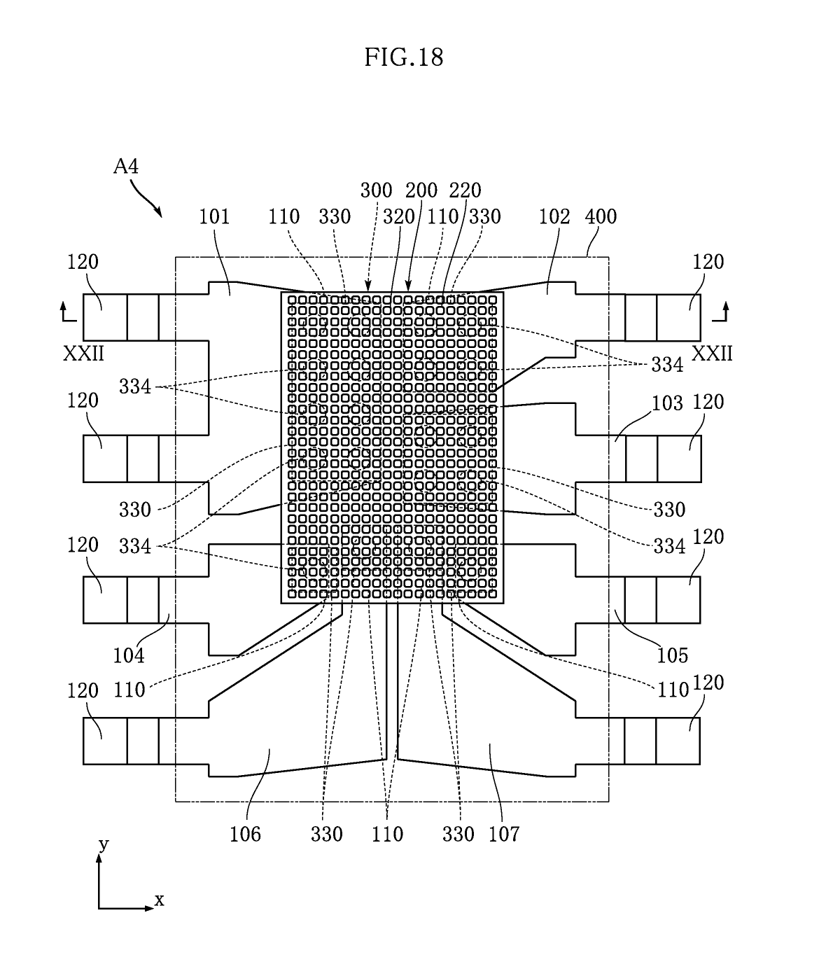

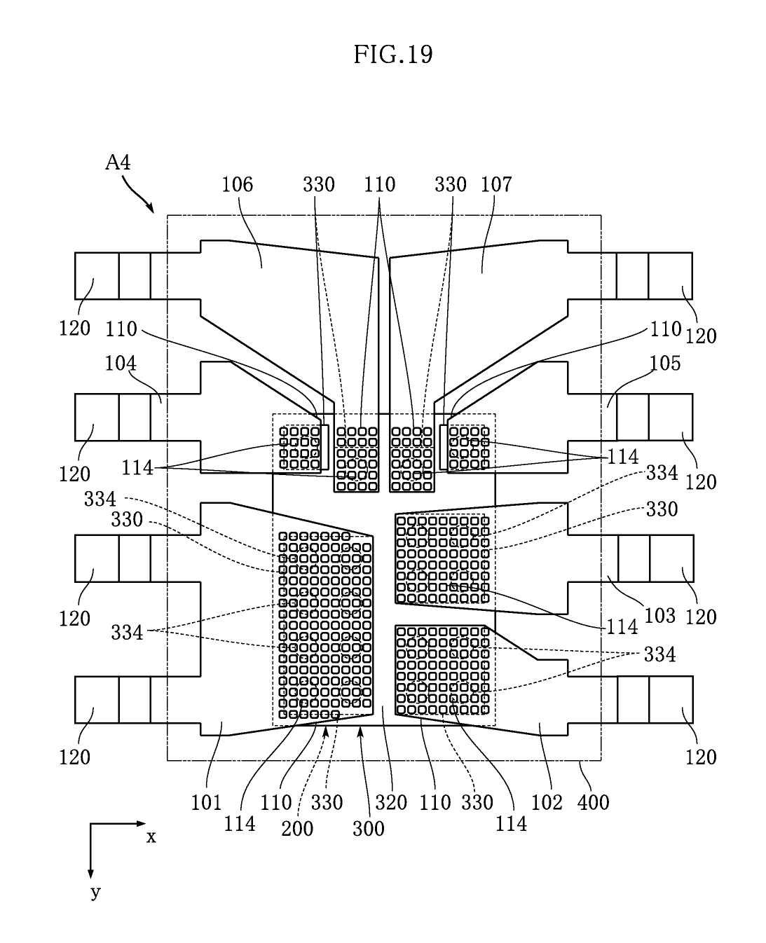

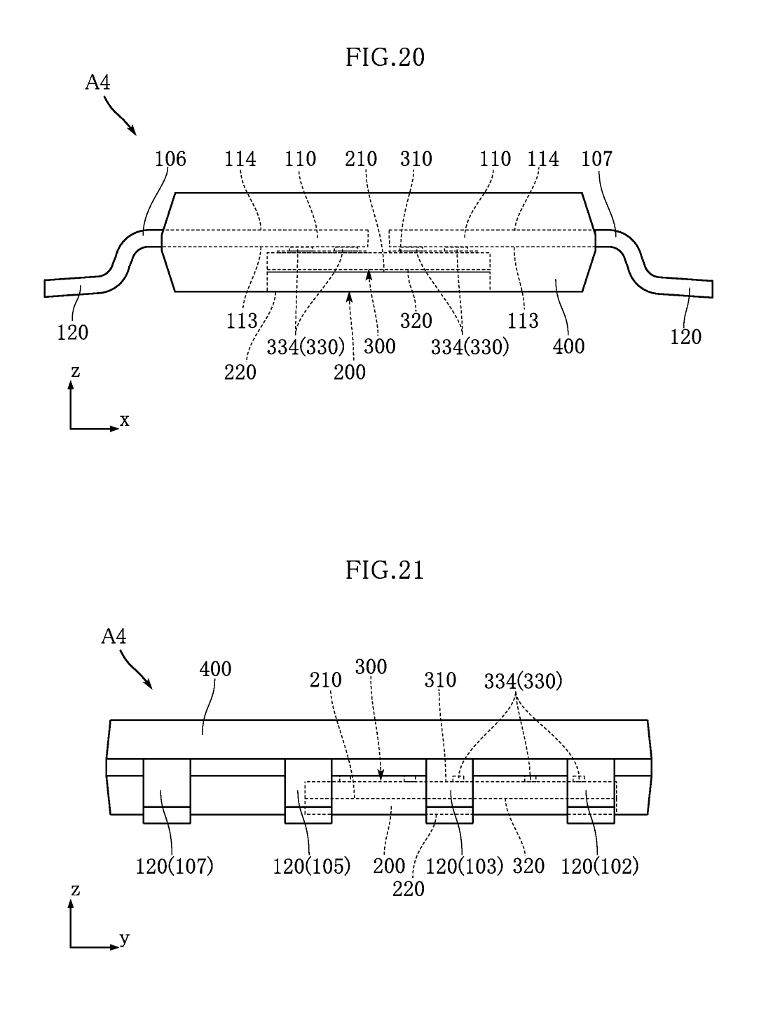

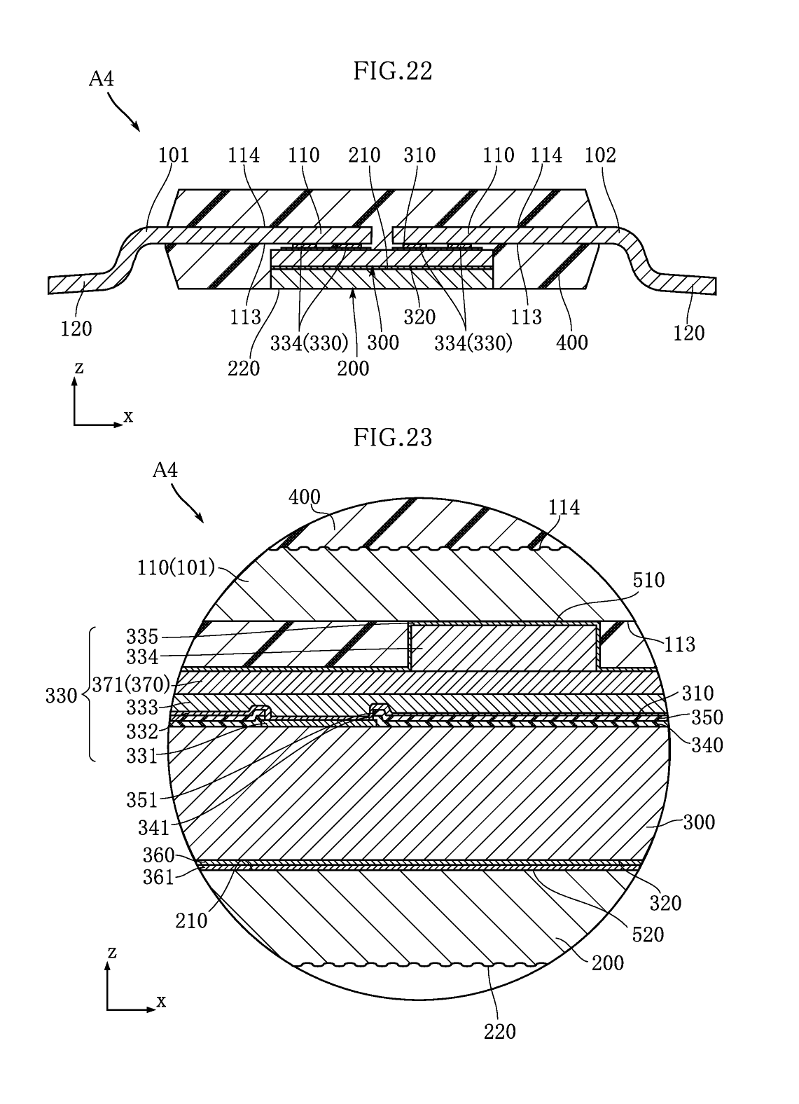

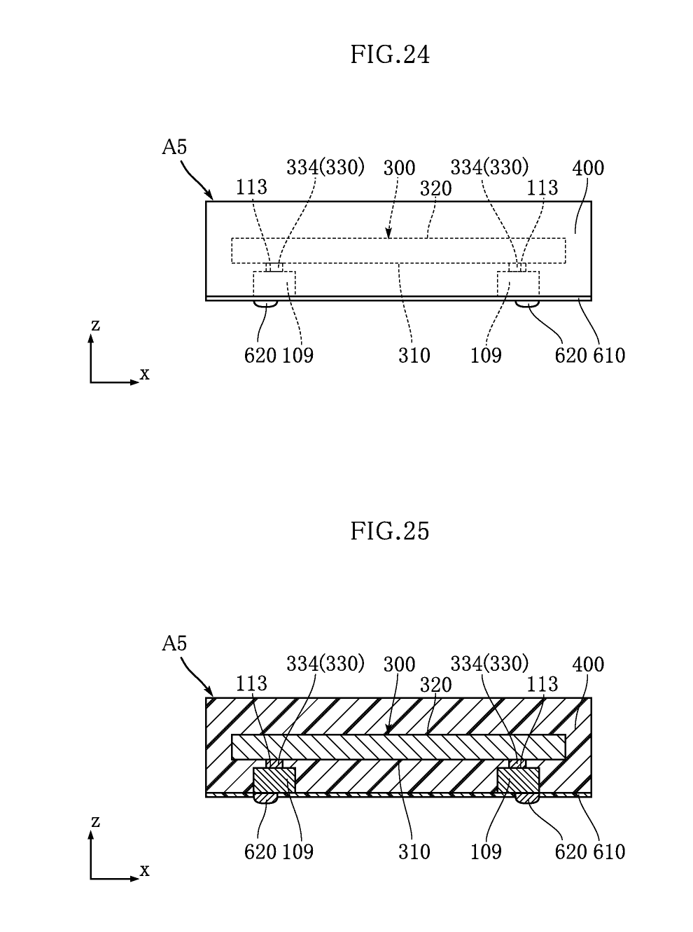

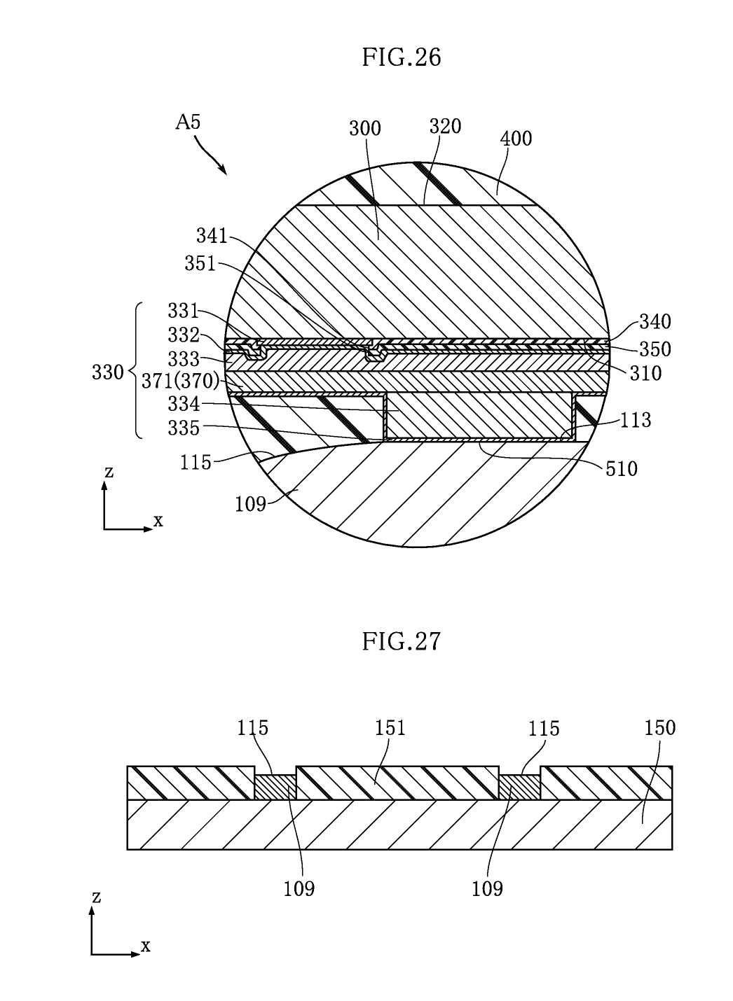

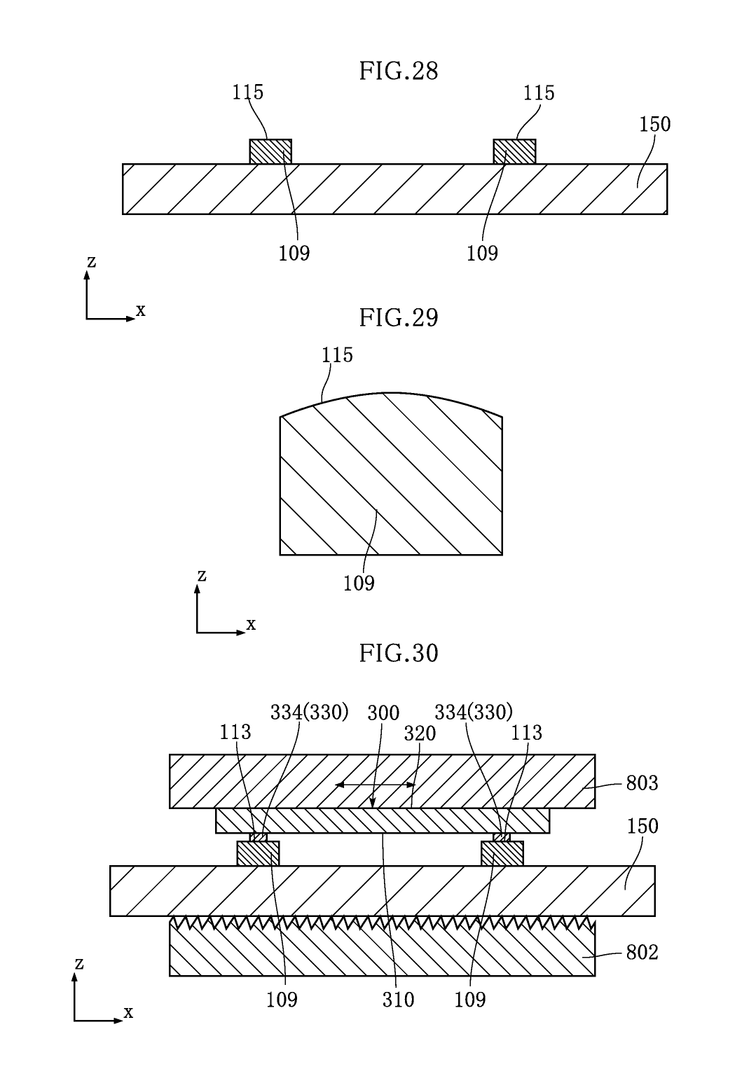

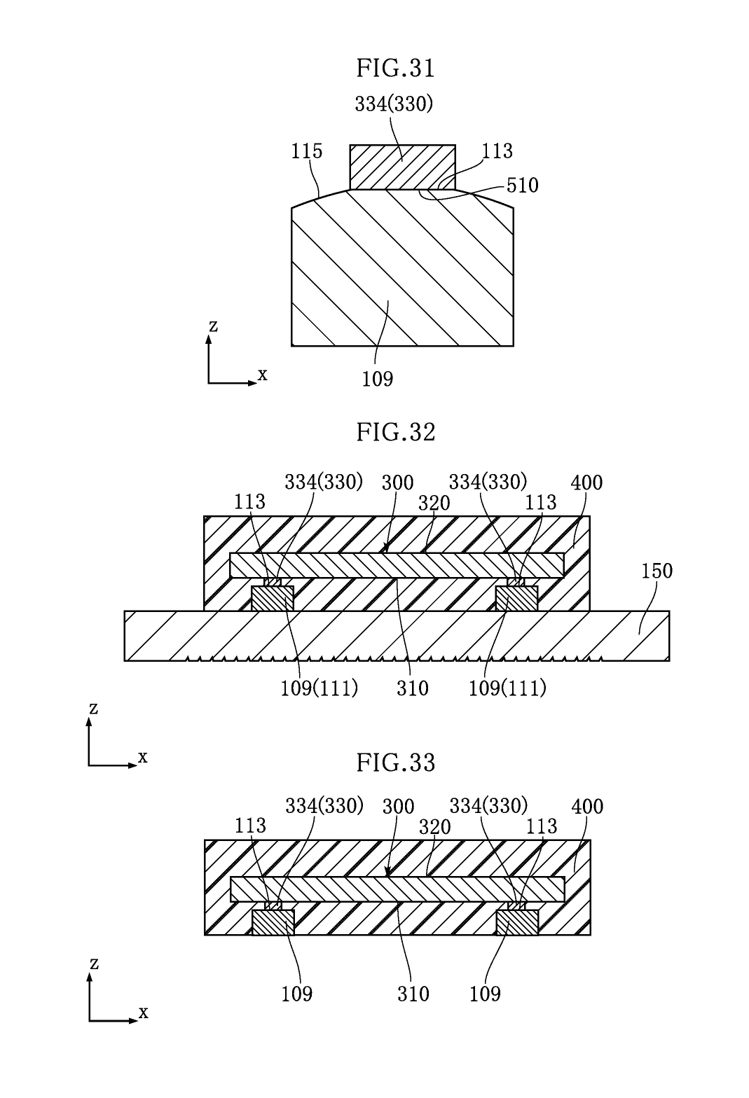

FIG. 6 is an enlarged sectional view showing an example of a method of making the semiconductor device of FIG. 1;

FIG. 9 is an enlarged sectional view showing an example of a method of making the semiconductor device of FIG. 1;

FIG. 10 is an enlarged sectional view showing an example of a method of making the semiconductor device of FIG. 1;

FIG. 11 is an enlarged sectional view showing an example of a method of making the semiconductor device of FIG. 1;

FIG. 12 is an enlarged sectional view showing an example of a method of making the semiconductor device of FIG. 1;

FIG. 13 is an enlarged sectional view showing an example of a method of making the semiconductor device of FIG. 1;

FIG. 14 is a sectional view showing an example of a method of making the semiconductor device of FIG. 1;

FIG. 15 is an enlarged sectional view showing an example of a method of making the semiconductor device of FIG. 1;

FIG. 16 is an enlarged sectional view showing a main section of a semiconductor device according to a second embodiment of the present disclosure;

FIG. 17 is an enlarged sectional view showing a main section of a semiconductor device according to a third embodiment of the present disclosure;

FIG. 18 is a plan view showing a semiconductor device according to a fourth embodiment of the present disclosure;

FIG. 19 is a bottom view showing the semiconductor device of FIG. 18;

FIG. 20 is a front view showing the semiconductor device of FIG. 18;

FIG. 21 is a side view showing the semiconductor device of FIG. 18;

FIG. 22 is a sectional view taken along lines XXII-XXII in FIG. 18;

FIG. 23 is an enlarged sectional view showing a main section of the semiconductor device of FIG. 18;

FIG. 24 is a front view showing a semiconductor device according to a fifth embodiment of the present disclosure;

FIG. 25 is a sectional view showing the semiconductor device of FIG. 24;

FIG. 26 is an enlarged sectional view showing a main section of the semiconductor device of FIG. 24;

FIG. 27 is a sectional view showing an example of a method of making the semiconductor device of FIG. 24;

FIG. 28 is a sectional view showing an example of a method of making the semiconductor device of FIG. 24;

FIG. 29 is an enlarged sectional view of an electroconductive support member;

FIG. 30 is a sectional view showing an example of a method of making the semiconductor device of FIG. 24;

FIG. 31 is an enlarged sectional view showing an example of a method of making the semiconductor device of FIG. 24;

FIG. 32 is an enlarged sectional view showing an example of a method of making the semiconductor device of FIG. 24;

FIG. 33 is an enlarged sectional view showing an example of a method of making the semiconductor device of FIG. 24;

FIG. 34 is an enlarged sectional view showing another example of an electroconductive support member;

FIG. 35 is an enlarged sectional view showing another example of a method of making the semiconductor device of FIG. 24;

FIG. 36 is an enlarged sectional view showing another example of a method of making the semiconductor device of FIG. 24;

FIG. 37 is an enlarged sectional view showing another example of a method of making the semiconductor device of FIG. 24; and

FIG. 38 is an enlarged sectional view showing another example of a method of making the semiconductor device of FIG. 24.

### MODE FOR CARRYING OUT THE INVENTION

Embodiments of the present disclosure are described below with reference to the drawings.

FIGS. 1-6 show a semiconductor device according to a first embodiment of the present disclosure. The semiconductor device A1 of this embodiment includes a plurality of (seven in this embodiment) leads 101-107, a semiconductor element 300 and a sealing resin 400.

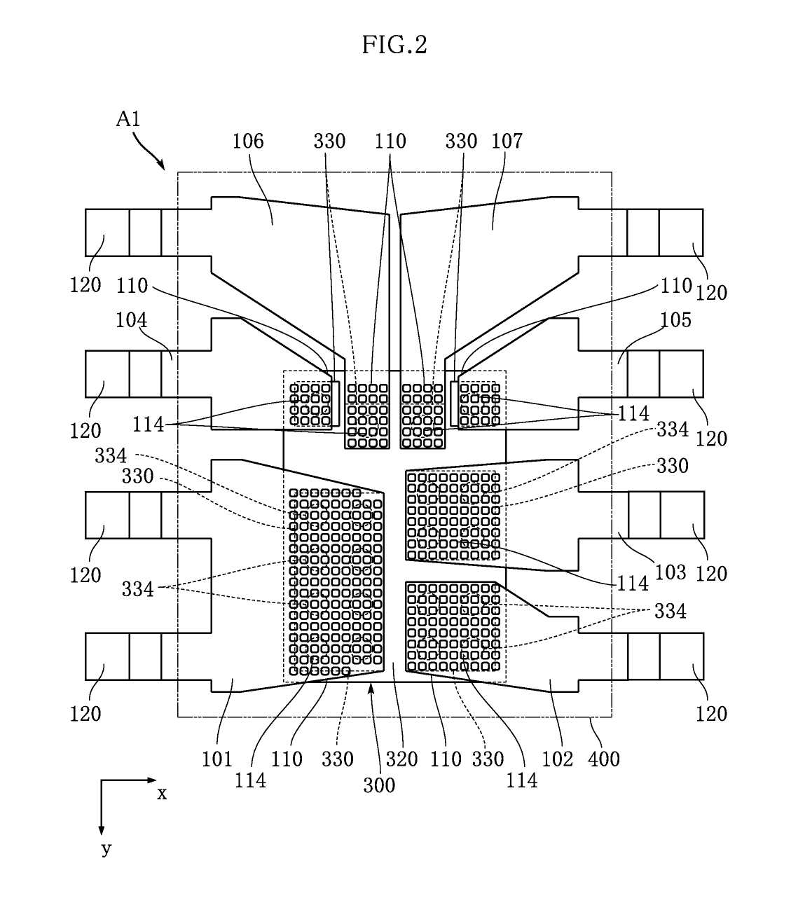

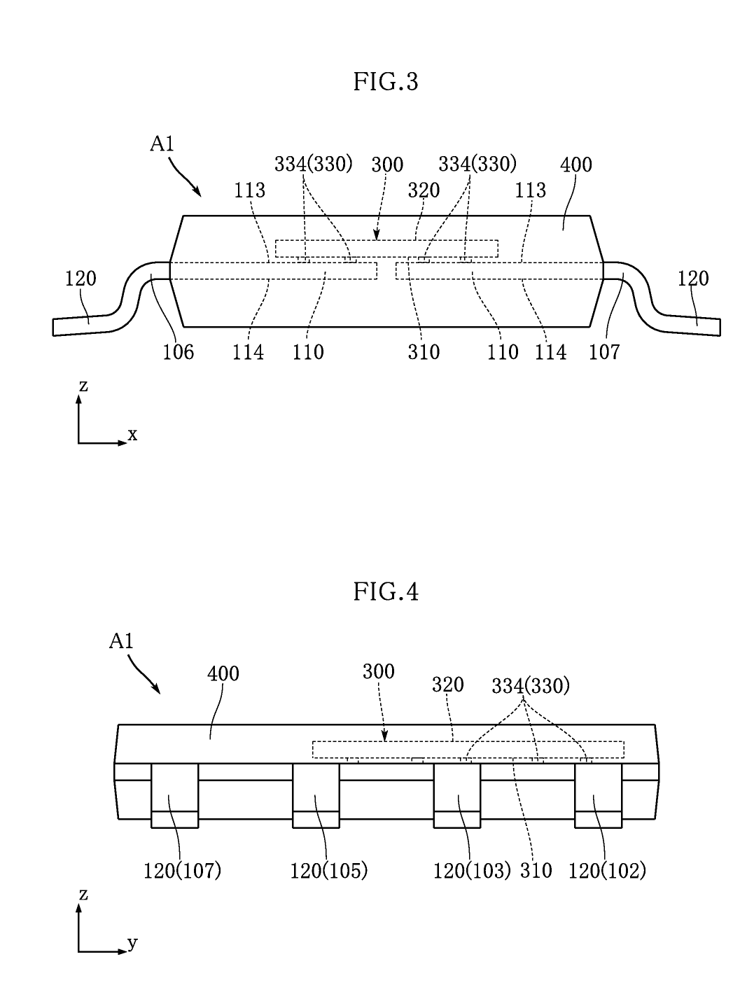

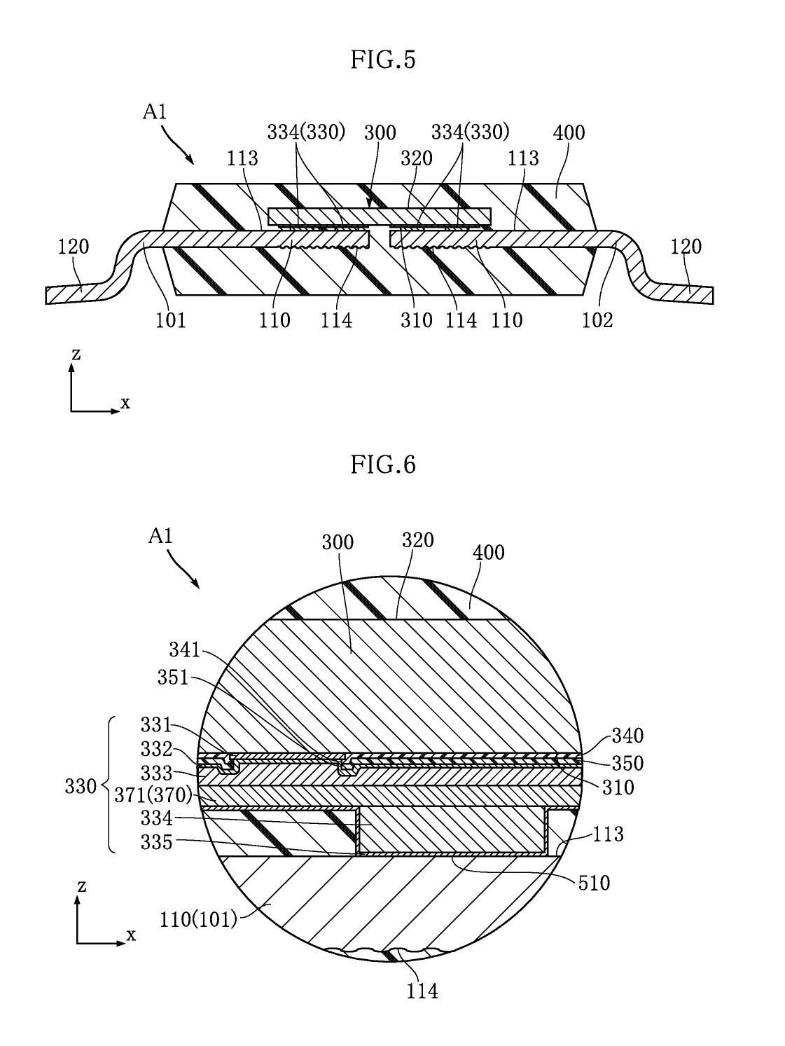

FIG. 1 is a plan view showing the semiconductor device A1. FIG. 2 is a bottom view showing the semiconductor device A1. FIG. 3 is a front view showing the semiconductor device A1. FIG. 4 is a side view showing the semiconductor device A1. FIG. 5 is a sectional view taken along lines V-V in FIG. 1. FIG. 6 is an enlarged sectional view showing a main section of the semiconductor device A1.

Each of the leads 101-107 is an example of the electroconductive support member according to the present disclosure. The leads 101-107 form a conduction path between the semiconductor element 300 and the outside of the semiconductor device A1 while supporting the semiconductor element 300. The leads 101-107 are made of metal. Examples of the metal forming the leads 101-107 include Cu, Ni, alloys of these, and 42 alloy. Plating layers of e.g. Ti, Ag, Pd, or Au may be provided on the surfaces of the leads 101-107. In this embodiment, the leads 101-107 are made of Cu. The thicknesses of the leads 101-107 are not limited and may be e.g. 50-500 μm or 100-150 μm. Each of the leads 101-107 includes a facing portion 110 and a terminal portion 120. The facing portion 110 overlaps the semiconductor element 300 in plan view and faces an electrode 330, which will be described later, of the semiconductor element 300. The terminal portion 120 extends to the outside of the sealing resin 400. The terminal portion 120 is used for mounting the semiconductor device A1 on e.g. a circuit board. As shown in FIGS. 3 and 5, each lead 101-107 has a bent portion between the facing portion 110 and the terminal portion 120. The lead 101 has two terminal portions 120.

As shown in FIG. 5, each facing portion 110 has a bonding surface 113 and a reverse surface 114. The bonding surface 113 faces the electrode 330 of the semiconductor element 300 and is bonded to the electrode 330. The reverse surface 114 is a surface opposite to the bonding surface 113. As shown in FIGS. 2 and 6, the reverse surface 114 of the facing portion 110 is irregular. The depth of the irregularities is e.g. about 20 μm.

Referring to FIG. 1, in this embodiment, the terminal portions 120 of the leads 101, 104 and 106 project to the left in FIG. 1. The terminal portions 120 of the leads 102, 103, 105 and 107 project to the right in FIG. 1. The facing portion 110 of the lead 101 is relatively large. The facing portions 110 of the leads 102 and 103 are smaller than the facing portion 110 of the lead 101 and arranged side by side in the y direction. The facing portion 110 of the lead 101 and the facing portions 110 of the leads 102 and 103 are arranged side by side in the x direction. The facing portions 110 of the leads 104, 105, 106 and 107 are smaller than the facing portions of the leads 102 and 103. The facing portions 110 of the leads 106 and 107 are arranged side by side in the x direction adjacent to the center in the x direction. The facing portions 110 of the leads 104 and 105 flank the facing portions 110 of the leads 106 and 107 in the x direction.

The semiconductor element 300 is an element that performs functions of the semiconductor device A1. For example, the semiconductor element 300 is, without limitation, a transistor, a diode or an LSI. As shown in FIG. 5, the semiconductor element 300 has a functional surface 310 and a reverse surface 320. The functional surface 310 is formed with a functional circuit (not shown) for perforating the functions of the semiconductor element 300. The reverse surface 320 is a surface opposite to the functional surface 310. The semiconductor element 300 is made from a wafer of e.g. Si.

The semiconductor element 300 is provided with a plurality of electrodes 330, a passivation film 340 and a protective film 350.

Each of the electrodes 330 is formed on the functional surface 310 and electrically connected to the corresponding lead 101-107. In this embodiment, seven electrodes 330 are provided correspondingly to the seven leads 101-107. These electrodes 330 have a common structure, though differing from each other in size and position.

In this embodiment, as shown in FIG. 1, the electrode 330 that faces the facing portion 110 of the lead 101 is relatively large and elongated in the y direction in plan view. The two electrodes 330 that face the facing portions 110 of the leads 102 and 103 are generally square in plan view, smaller than the electrode 330 that faces the facing portion 110 of the lead 101, and arranged side by side in the y direction. The electrode 330 that faces the facing portion 110 of the lead 101 and the two electrodes 330 that face the facing portions 110 of the leads 102 and 103 are arranged side by side in the x direction. The four electrodes 330 that face the facing portions 110 of the leads 104, 105, 106 and 107 are smaller than the two electrodes 330 that face the facing portions 110 of the leads 102 and 103 and generally square in plan view. The two electrodes 330 that face the facing portions 110 of the leads 106 and 107 are arranged side by side in the x direction adjacent to the center in the x direction. The two electrodes 330 that face the facing portions 110 of the leads 104 and 105 flank the facing portions 110 of the leads 106 and 107 in the x direction.

As shown in FIG. 6, each electrode 330 has a base layer 331, a foundation layer 332, a re-distribution layer 333, a reinforcing layer 370, a projection 334 and a bond promoting layer 335.

The base layer 331 is in contact with the functional surface 310 and is electrically connected directly to appropriate portions of the functional circuit formed on the functional surface 310. The base layer 331 is made of e.g. Al. For example, the base layer 331 is 0.1-10 μm in thickness.

The passivation flint 340 and the protective film 350 are described below. The passivation film 340 is formed on the functional surface 310. The passivation film 340 prevents an excessive force from being applied to a silicon member, which is the main body of the semiconductor element 300. The passivation film 340 is made of an insulating material such as SiN. For example, the passivation film 340 is 200 nm to 3 μm in thickness. The protective film 350 is formed on the passivation film 340, prevents an excessive force from being applied to a silicon member, which is the main body of the semiconductor element 300, and facilitates formation of the re-distribution layer 333. The protective film 350 is made of an insulating material such as polyimide. For example, the protective film 350 is about 5 μm in thickness.

The passivation film 340 is formed with a through-hole 341, and the base layer 331 is positioned in the through-hole 341. In this embodiment, the passivation film 340 covers side edges of the base layer 331. The protective film 350 is formed with a through-hole 351 at a position corresponding to the through-hole 341 in plan view, thereby exposing the surface of the base layer 331.

The foundation layer 332 serves as a foundation for forming the re-distribution layer 333. The foundation layer 332 corresponds in shape to the electrode 330 in plan view. The foundation layer 332 covers the surface portion of the base layer 331 which is exposed from the passivation film 340 and protective film 350, the side edges of the passivation film which define the through-hole 341, the side edges of the protective film 350 which define the through-hole 351, and appropriate portions of the protective film 350. For example, the foundation layer 332 is made of one of Ti, W or Ta. For example, the foundation layer 332 is about 100 nm in thickness.

The re-distribution layer 333 forms the main portion of the electrode 330 and is larger than the base layer 331 in plan view. The material for the re-distribution layer 333 is not limitative. In this embodiment, the re-distribution layer 333 is made of Cu. For example, the re-distribution layer 333 is about 10 μm in thickness.

The reinforcing layer 370 is provided on the functional surface 310 and reinforces the electrode 330. In this embodiment, the reinforcing layer 370 is provided between the reinforcing layer 333 and the projection 334. The reinforcing layer 370 of this embodiment consists solely of a first electroconductive layer 371. The first electro-conductive layer 371 is a layer made of a single metal and made of Ni in this embodiment. For example, the first electroconductive layer 371 is 3-20 μm in thickness.

The projection 334 is formed on the first electroconductive layer 371 so as to project from the first electroconductive layer 371. The projection 334 may be made of any conductive material and is made of Cu in this embodiment. The shape of the projection 334 is not limitative but is columnar in this embodiment. For example, the size of the projection 334 is 25-200 μm in diameter and 10-500 μm in height. The projection 334 does not overlap the base layer 331 in plan view and is provided at a position avoiding the base layer 331. The projection 334 overlaps the passivation film 340 and the protective film 350 in plan view.

In this embodiment, as shown in FIG. 1, each of the three electrodes 330 that face the facing portions 110 of the leads 101, 102 and 103, respectively, is formed with a plurality of projections 334. Specifically, eight projections 334 are formed in four rows and two columns in the electrode 330 that faces the facing portion 110 of the lead 101. Four projections 334 are formed in two rows and two columns in each of the electrodes 330 that face the facing portions 110 of the leads 102 and 103. One projection 334 is formed on each of the electrodes 330 that face the facing portions 110 of the leads 104-107.

The bond promoting layer 335 forms the outermost layer of the electrode 330 and covers the projection 334 and the first electroconductive layer 371 in this embodiment. The bond promoting layer 335 strengthens the bonding between each of the electrodes 330 and the facing portion 110 of the corresponding lead 101-107. The bond promoting layer 335 includes at least one of Ni or Pd and in this embodiment consists of a Ni layer directly covering the projection 334 and the first electroconductive layer 371 and a Pd layer formed on the Ni layer. For example, the bond promoting layer 335 is about 100 nm to 10 μm in thickness. Other examples of the material for the bond promoting layer 335 include Cu, Al, Ti and Au.

Each electrode 330 and the facing portion 110 of the corresponding lead 101-107 are bonded together by solid state welding. Specifically, the top surface of the projection 334 and the bonding surface 113 of the facing portion 110 are solid-state welded. Thus, as shown in FIG. 6, the semiconductor device A1 includes a first solid-state welded portion 510 where the top surface of the projection 334 and part of the bonding surface 113 of the facing portion 110 are bonded together in the solid state welding state. Note that in this embodiment the bond promoting layer 335 is interposed between the projection 334 and the bonding surface 113 of the facing portion 110. In addition to or instead of forming the bond promoting layer 335 on the electrode 330, the bond promoting layer may be formed on the bonding surface 113 of the facing portion 110.

The sealing resin 400 covers the entirety of the semiconductor element 300 and the leads 101-107 except the terminal portions 120. The sealing resin 400 is made of an insulating material and made of e.g. black epoxy resin in this embodiment. In this embodiment, the sealing resin 400 also fills the space between the bonding surface 113 of the facing portion 110 and the bond promoting layer 335 of the electrode 330 at regions avoiding the projection 334.

An example of a method of making the semiconductor device A1 is described below.

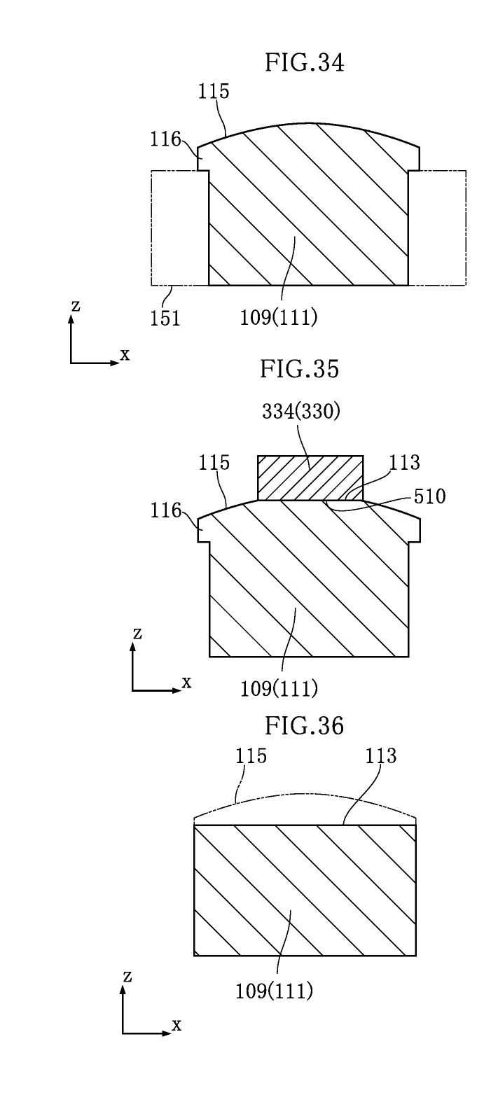

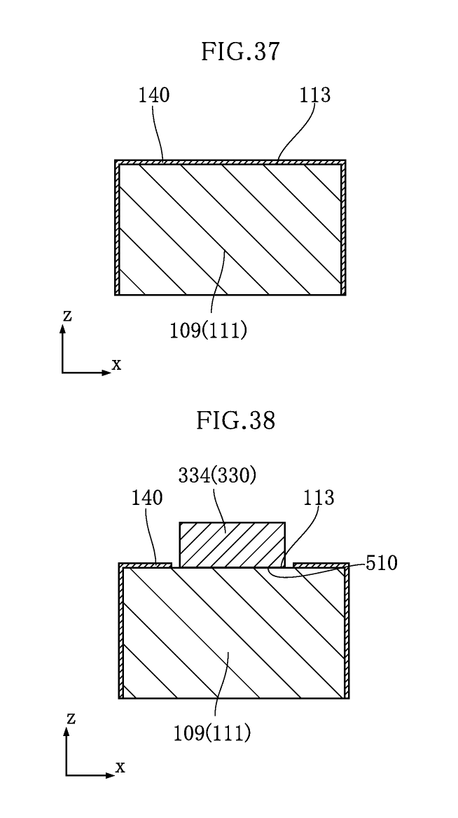

First, a base layer 331 is formed on a semiconductor element 300, as shown in FIG. 7. Specifically, the base layer 331 is formed so as to be electrically connected to appropriate portions of the functional circuit (not shown) on the functional surface 310 of the semiconductor element 300. The base layer 331 is formed in a pattern by e.g. plating using Al. The base layer 331 is formed to have a thickness of e.g. 0.1-10 μm.

Then, a passivation film 340 and a protective film 350 are formed, as shown in FIG. 8. Specifically, a SiN film, for example, is formed to have a thickness of e.g. 200 nm to 3 μm on the entirety of the functional surface 310. Then, a polyimide file, for example, formed to have a thickness of e.g. about 5 μm on the SiN trim. Then, a through-hole 341 and a through-hole 351 are formed in the SiN film and the polyimide film by patterning using e.g. etching to expose the base layer 331. Thus, the passivation film 340 and the protective film 350 are obtained.

Then, a foundation layer 332 is formed as shown in FIG. 9. Specifically, a film of e.g. one of Ti, W or Ta is formed to have a thickness of about 100 nm on the protective film 350 and the base layer 331 exposed through the through-holes 341 and 351, thereby covering the protective film 350 and the base layer 331. In this process, this film is formed so as to also cover the side edges of the passivation film 340 and protective film 350 that define the through-hole 341 and the through-hole 351. The film format ion method is not limitative, and e.g. CVD or sputtering may be employed. Note that the foundation layer 332 is formed in such a manner that its shape, size and position corresponds to those of the electrode 330 to be formed.

Then, a re-distribution layer 333 is formed as shown in FIG. 10. Specifically, the re-distribution layer 333 is formed on the foundation layer 332 by e.g. electroplating. The re-distribution layer 333 is formed from Cu to have a thickness of about 10 μm. The re-distribution layer 333 is formed in such a manner that its shape, size and position generally correspond to those of the foundation layer 332.

Then, as shown in FIG. 11, a first electroconductive layer 371 as the reinforcing layer 370 is formed on the re-distribution layer 333. The first electroconductive layer 371 is formed by e.g. plating. For example, the first electroconductive layer 371 is formed from Ni to have a thickness of about 3 to 20 μm. The first electroconductive layer 371 is formed in such a manner that its shape, size and position generally correspond to those of the foundation layer 332.

Then, a projection 334 is formed as shown in FIG. 12. For example, the formation of the projection 334 may be performed by combining plating or sputtering and patterning. For example, a mask with an opening corresponding to the shape of the projection 334 is prepared, and Cu is applied to the first electroconductive layer 371 by plating or sputtering using the mask, whereby the projection 334 is formed. Alternatively, the projection 334 may be formed by forming a Cu film on the first electroconductive layer 371 by plating or sputtering and then patterning the Cu film by e.g. etching. Note that the projection 334 is formed at a position avoiding the base layer 331.

Then, a bond promoting layer 335 is formed as shown in FIG. 13. The formation of the bond promoting layer 335 is performed by successively forming a Ni layer and a Pd layer by e.g. plating so as to cover the first electroconductive layer 371 and the projection 334. The bond promoting layer 335 is formed to have a thickness of e.g. 100 nm to 10 μm.

Then, as shown in FIG. 14, the bonding surfaces 113 of the facing portions 110 of the leads 101-107 and the electrodes 330 of the semiconductor element 300 are bonded together. For example, in this bonding process, with the semiconductor element 300 fixed on a table 801, a jig 802 is pressed against the reverse surfaces 114 of the facing portions 110 of the leads 101-107. The jig 802 is formed with a plurality of projections on its lower surface in the figure. With a predetermined pressing force applied from the jig 802 to the leads 101-107, the jig 802 is vibrated within the xy-plane. The frequency of this vibration is lower than e.g. that of an ultrasonic wave and may be e.g. 100 Hz or less, or specifically, 50 to 60. Hz. This process allows the projection 334 and the facing portion 110 to be solid-state welded via the bond promoting layer 335, as shown in FIG. 15. Thus, the first solid-state welded portion 510 is formed. The reverse surface 114 of the facing portion 110 becomes irregular as a result of the pressing of the jig 802 against the surface.

Thereafter, a step of e.g. forming a sealing resin 400 is performed, whereby the semiconductor device A1 is obtained.

The advantages of the semiconductor device A1 are described below.

According to this embodiment, the projections 334 and the leads 101-107 are bonded to each other by solid state welding. As described above, solid state welding is the bonding by which two members are directly bonded to each other and does not require any bonding medium such as a wire or solder intervening between the two. Thus, solid state welding realizes higher bonding strength and higher bonding reliability. Moreover, solid state welding can be performed collectively to all the projections 334 and facing portions 110 of the leads 101-107, which leads to an enhancement in the manufacturing efficiency of the semiconductor device. Since the reinforcing layer 370 is provided, the electrode or the semiconductor element is prevented from being damaged by the force applied in the solid state welding. The reinforcing layer 370 constituting of the first electroconductive layer 371 made of Ni is suitable for projecting the functional surface 310.

Owing to the provision of the projection 334, the bonding area between the electrode 330 and the facing portion 110 of the lead 101-107 is reduced. This leads to a reduction of the force that needs to be applied to achieve a predetermined bonding pressure in the solid state welding process. Thus, the semiconductor element 300 is more reliably prevented from being damaged by the bonding pressure. Moreover, owing to the provision of the projection 334, a space for loading the sealing resin 400 is defined between the functional surface 310 of the semiconductor element 300 and the bonding surface 113 of the facing portion 110 of the lead 101-107. Loading the sealing resin 400 in such a space assures that necessary insulation is reliably provided in the semi conductor device A1.

Arranging the projection 334 so as not to overlap the base layer 331 in plan view prevents an excessive force from being applied to a silicon member, which is the main body of the semiconductor element 300, in solid state welding. Moreover, since the projection 334 overlaps the passivation film 340 and the protective film 350 in plan view, the force applied during the solid state welding is absorbed by the passivation film 340 and the protective film 350.

Provision of the bond promoting layer 335 enhances the reliability of the solid state welding between the projection 334 and the facing portion 110.

FIGS. 16-38 show other embodiments of the present disclosure. In these figures, the elements that are identical or similar to those of the foregoing embodiment are designated by the same reference signs as those used for the foregoing embodiment.

FIG. 16 shows a semiconductor device according to a second embodiment of the present disclosure. The semiconductor device A2 of this embodiment differs from the foregoing semiconductor device A1 in structure of the reinforcing layer 370.

In this embodiment, the reinforcing layer 370 comprises a first electroconductive layer 371, a second electroconductive layer 372 and a third electroconductive layer 373. The second electroconductive layer 372 is formed on the lower surface in FIG. 16 of the first electroconductive layer 371. The second electroconductive layer 372 is made of e.g. Ti. For example, the second electroconductive layer 372 is about 0.1 μm in thickness.

The third electroconductive layer 373 is formed on the lower surface in FIG. 16 of the second electroconductive layer 372. The third electroconductive layer 373 is made of e.g. Cu. For example, the third electroconductive layer 373 is about 3 μm in thickness.

This embodiment also enhances the manufacturing efficiency of the semiconductor device without causing damage to the functional surface 310. Also, the solid state welding of the projection 334 and the facing portion 110 of the lead 101-107 realizes higher bonding strength and higher bonding reliability. Moreover, since the reinforcing layer 370 is made up of the first electroconductive layer 371, the second electroconductive layer 372 and the third electroconductive layer 373, the functional surface 310 is protected more reliably.

FIG. 17 shows a semiconductor device according to a third embodiment of the present disclosure. The semiconductor device A3 of this embodiment differs from the semiconductor devices A1 and A2 mainly in structure of the reinforcing layer 370 and the re-distribution layer 333.

In this embodiment, the foundation layer 332 overlaps the base layer 331, and the projection 334 is formed on the foundation layer 332 by utilizing the foundation layer 332. Thus, the projection 334 overlaps the base layer 331 in plan view.

The reinforcing layer 370 comprises an insulating layer 374. The insulating layer 374 is made of an insulating material and made of polyimide in this embodiment. The insulating layer 374 is formed so as to cover the protective film 350. The insulating layer 374 is formed with a through-hole 374a. The through-hole 374a penetrates the insulating layer 374 in the thickness direction and receives the projection 334.

For example, the projection 334 and the insulating layer 374 are formed as follows. First, a resist film is formed to cover the protective film 350, and then a through-hole is formed in the resist film. Then, Cu-plating is performed to fill the through-hole to form the projection 334. Then, the resist film is removed. Then, the insulating layer 374 is formed by using a polyimide resin material.

In this embodiment, the re-distribution layer 333 is provided on the opposite side of the functional surface 310 with respect to the projection 334. To form the re-distribution layer 333, a foundation layer may be formed on the outer surface the insulating layer 374. On the outer surface of the re-distribution layer 333 is formed the bond promoting layer 335.

This embodiment also enhances the manufacturing efficiency of the semiconductor device without causing damage to the functional surface 310. Also, the solid state welding of the projection 334 and the facing portion 110 of the lead 101-107 realizes higher bonding strength and higher bonding reliability. Moreover, since the re-distribution layer 333 is provided on the outer side of the projection 334, the external force or load to the projection 334 is more distributed.

FIGS. 18-23 show a semiconductor device according to a fourth embodiment of the present disclosure. The semiconductor device A4 of this embodiment includes leads 101-107, a heat dissipation member 200, a semiconductor element 300 and a sealing resin 400.

FIG. 18 is a plan view showing the semiconductor device A4. FIG. 19 is a bottom view showing the semiconductor device A4. FIG. 20 is a front view showing the semiconductor device A4. FIG. 21 is a side view showing the semiconductor device A4. FIG. 22 is a sectional view taken along lines XXII-XXII in FIG. 18. FIG. 23 is an enlarged sectional view showing a main section of the semiconductor device A4.

Each of the leads 101-107 is an example of the electroconductive support member according to the present disclosure. The leads 101-107 form a conduction path between the semiconductor element 300 and the outside of the semiconductor device A4 while supporting the semiconductor element 300. The leads 101-107 are made of metal. Examples of the metal forming the leads 101-107 include Cu, Ni, alloys of these, and 42 alloy. Plating layers of e.g. Ti, Ag, Pd, or Au may be provided on the surfaces of the leads 101-107. In this embodiment, the leads 101-107 are made of Cu. The thicknesses of the leads 101-107 are not limited and may be e.g. 50-500 μm or 100-150 μm.

Each of the leads 101-107 includes a facing portion 110 and a terminal portion 120. The facing portion 110 overlaps the semiconductor element 300 in plan view and faces an electrode 330, which will be described later, of the semiconductor element 300. The terminal portion 120 extends to the outside of the sealing resin 400. The terminal portion 120 is used for mounting the semiconductor device A4 on e.g. a circuit board. As shown in FIGS. 20 and 22, each lead 101-107 has a bent portion between the facing portion 110 and the terminal portion 120. The lead 101 has two terminal portions 120.

As shown in FIG. 22, each facing portion 110 has a bonding surface 113 and a reverse surface 114. The bonding surface 113 faces the electrode 330 of the semiconductor element 300 and is bonded to the electrode 330. The reverse surface 114 is a surface opposite to the bonding surface 113. As shown in FIGS. 19 and 23, the reverse surface 114 of the facing portion 110 is irregular. The depth of the irregularities is e.g. about 20 μm.

Referring to FIG. 18, in this embodiment, the terminal portions 120 of the leads 101, 104 and 106 project to the left in FIG. 18. The terminal portions 120 of the leads 102, 103, 105 and 107 project to the right in FIG. 18. The facing portion 110 of the lead 101 is relatively large. The facing portions 110 of the leads 102 and 103 are smaller than the facing portion 110 of the lead 101 and arranged side by side in the y direction. The facing portion 110 of the lead 101 and the facing portions 110 of the leads 102 and 103 are arranged side by side in the x direction. The facing portions 110 of the leads 104, 105, 106 and 107 are smaller than the facing portions of the leads 102 and 103. The facing portions 110 of the leads 106 and 107 are arranged side by side in the x direction adjacent to the center in the x direction. The facing portions 110 of the leads 104 and 105 flank the facing portions 110 of the leads 106 and 107 in the x direction.

The heat dissipation member 200 is bonded to the semiconductor element 300 to promote heat dissipation from the semiconductor element 300. The heat dissipation member 200 is made of metal. Examples of the metal for forming the heat dissipation member 200 include Cu, Ni, alloys of these, and 42 alloy. Plating layers of e.g. Ti, Ag, Pd, or Au may be formed on the surfaces of the heat dissipation member 200. The thickness of the heat dissipation member 200 is, without limitation, e.g. 50-500 μm or 100-150 μm. In this embodiment, the heat dissipation member 200 is formed from Cu, along with the leads 101-107. In this case, in the process of making the semiconductor device A4, the leads 101-107 and the heat dissipation member 200 are formed from a common plate-like member. Bending part of the plate-like member through 180° about an axis extending in the y direction provides the leads 101-107 and the heat dissipation member 200 that face each other with the semiconductor element 300 intervening between the leads and the semiconductor element.

As shown in FIGS. 22 and 23, the heat dissipation member 200 has a bonding surface 210 and a reverse surface 220. The bonding surface 210 is bonded to the semiconductor element 300. The reverse surface 220 is a surface opposite to the bonding surface 210. In this embodiment, the reverse surface 220 is exposed from the sealing resin 400. As shown in FIGS. 18 and 23, the reverse surface 220 is irregular. The depth of the irregularities is e.g. about 20 μm.

The semiconductor element 300 is an element that performs functions of the semiconductor device A4. For example, the semiconductor element 300 is, without limitation, a transistor, a diode or an LSI. As shown in FIG. 22, the semiconductor element 300 has a functional surface 310 and a reverse surface 320. The functional surface 310 is formed with a functional circuit (not shown) for performing the functions of the semiconductor element 300. The reverse surface 320 is a surface opposite to the functional surface 310. The semiconductor element 300 is made from a wafer of e.g. Si.

The semiconductor element 300 includes a plurality of electrodes 330, a passivation film 340, a protective film 300, a reverse surface metal layer 360 and a bond promoting layer 361.

Each of the electrodes 330 is formed on the functional surface 310 and electrically connected to the corresponding lead 101-107. In this embodiment, seven electrodes 330 are provided correspondingly to the seven leads 101-107. These electrodes 330 have a common structure, though differing from each other in size and position.

In this embodiment, as shown in FIG. 18, the electrode 330 that faces the facing portion 110 of the lead 101 is relatively large and elongated in the y direction in plan view. The two electrodes 330 that face the facing portions 110 of the leads 102 and 103 are generally square in plan view, smaller than the electrode 330 that faces the facing portion 110 of the lead 101, and arranged side by side in the y direction. The electrode 330 that faces the facing portion 110 of the lead 101 and the two electrodes 330 that face the facing portion 110 of the lead 102 and the lead 103 are arranged side by side in the x direction. The four electrodes 330 that face the facing portions 110 of the leads 104, 105, 106 and 107 are smaller than the two electrodes that face the facing portions 110 of the leads 102 and 103 and generally square in plan view. The two electrodes 330 that face the facing portions 110 of the leads 106 and 107 are arranged side by side in the x direction adjacent to the center in the x direction. The two electrodes 330 that face the facing portions 110 of the leads 104 and 105 flank the facing portions 110 of the leads 106 and 107 in the x direction.

As shown in FIG. 23, each electrode 330 has a base layer 331, a foundation layer 332, a re-distribution layer 333, a reinforcing layer 370, a projection 334 and a bond promoting layer 335.

The base layer 331 is in contact with the functional surface 310 and is electrically connected directly to appropriate portions of the functional circuit formed on the functional surface 310. The base layer 331 is made of e.g. Al. For example, the base layer 331 is 0.1-10 μm in thickness.

The passivation film 340 and the protective film 350 are described below. The passivation film 340 is formed on the functional surface 310. The passivation film 340 prevents an excessive force from being applied to a silicon member, which is the main body of the semiconductor element 300. The passivation film 340 is made of an insulating material such as SiN. For example, the passivation film 340 is 200 nm to 3 μm in thickness. The protective film 350 is formed on the passivation film 340, prevents an excessive force from being applied to a silicon member, which is the main body of the semiconductor element 300, and facilitates formation of the re-distribution layer 333. The protective film 350 is made of an insulating material such as polyimide. For example, the protective film 350 is about 5 μm in thickness.

The passivation film 340 is formed with a through-hole 341, and the base layer 331 is positioned in the through-hole 341. In this embodiment, the passivation film 340 covers side edges of the base layer 331. The protective film 350 is formed on the passivation film 340. The protective film 350 is formed with a through-hole 351 at a position corresponding to the through-hole 341 in plan view, thereby exposing the surface of the base layer 331.

The foundation layer 332 serves as a foundation for forming the re-distribution layer 333. The foundation layer 332 corresponds in shape to the electrode 330 in plan view. The foundation layer 332 covers the surface portion of the base layer 331 which is exposed from the passivation film 340 and protective film 350, the side edges of the passivation film which define the through-hole 341, the side edges of the protective film 350 which define the through-hole 351, and appropriate portions of the protective film 350. For example, the foundation layer 332 is made of one of Ti, W or Ta. For example, the foundation layer 332 is about 100 nm in thickness.

The re-distribution layer 333 forms the main portion of the electrode 330 and is larger than the base layer 331 in plan view. The material for the re-distribution layer 333 is not limitative. In this embodiment, the re-distribution layer 333 is made of Cu. For example, the re-distribution layer 333 is about 10 μm in thickness.

The reinforcing layer 370 is provided on the functional surface 310 and reinforces the electrode 330. In this embodiment, the reinforcing layer 370 is provided between the reinforcing layer 333 and the projection 334. The reinforcing layer 370 of this embodiment consists solely of a first electroconductive layer 371. The first electroconductive layer 371 is a layer made of a single metal and made of Ni in this embodiment. For example, the first electroconductive layer 371 is 3-20 μm in thickness. Although the illustrated reinforcing layer 370 has the same structure as that of the reinforcing layer 370 of the semiconductor device A1, the reinforcing layer 370 of the semiconductor device A2 or the semiconductor device A3 may be applied to this embodiment.

The projection 334 is formed on the first electroconductive layer 371 so as to project from the first electroconductive layer 371. The projection 334 may be made of any conductive material and made of Cu in this embodiment. The shape of the projection 334 is not limitative, and columnar in this embodiment. For example, the size of the projection 334 is 25-200 μm in diameter and 10-500 μm in height. The projection 334 does not overlap the base layer 331 in plan view and is provided at a position avoiding the base layer 331. The projection 334 overlaps the passivation film 340 and the protective film 350 in plan view.

In this embodiment, as shown in FIG. 18, each of the three electrodes 330 that face the facing portions 110 of the leads 101, 102 and 103, respectively, is formed with a plurality of projections 334. Specifically, eight projections 334 are formed in four rows and two columns in the electrode 330 that faces the facing portion 110 of the lead 101. Four projections 334 are formed in two rows and two columns in each of the electrodes 330 that face the facing portions 110 of the leads 102 and 103. One projection 334 is formed on each of the electrodes 330 that face the facing portions 110 of the leads 104-107.

The bond promoting layer 335 forms the outermost layer of the electrode 330 and covers the projection 334 and the first electroconductive layer 371 in this embodiment. The bond promoting layer 335 strengthens the bonding between each of the electrodes 330 and the facing portion 110 of the corresponding lead 101-107. The bond promoting layer 335 includes at least one of Ni or Pd and in this embodiment consists of a Ni layer directly covering the projection 334 and the first electroconductive layer 371 and a Pd layer formed on the Ni layer. For example, the bond promoting layer 335 is about 100 nm to 10 μm in thickness. Other examples of the material for the bond promoter layer 335 include Cu, Al, Ti and Au.

Each electrode 330 and the facing portion 110 of the corresponding lead 101-107 are bonded together by solid state welding. Specifically, the top surface of the projection 334 and the bonding surface 113 of the facing portion 110 are solid-state welded. Thus, as shown in FIG. 23, the semiconductor device A4 includes a solid-state welded portion 510 where the top surface of the projection 334 and part of the bonding surface 113 of the facing portion 110 are bonded together in the solid state welding state. Note that in this embodiment the bond promoting layer 335 is interposed between the projection 334 and the bonding surface 113 of the facing portion 110. In addition to or instead of forming the bond promoting layer 335 on the electrode 330, the bond promoting layer may be formed on the bonding surface 113 of the facing portion 110.

The reverse surf ace metal layer 360 is formed on the reverse surface of the semiconductor element 300 and in this embodiment covers the entirety of the reverse surface 320. The reverse surface metal layer 360 is made of a metal such as Cu, Al, Ti or Au. For example, the reverse surface metal layer 360 is 0.1-10 μm in thickness.

The bond promoting layer 361 is formed on the reverse surface metal layer 360. The bond promoting layer 361 includes at least one of Ni or Pd and in this embodiment consists of a Ni layer directly covering the reverse surface 320 and a Pd layer formed on the Ni layer. For example, the bond promoting layer 361 is about 100 nm to 10 μm in thickness. Other examples of the material for the bond promoting layer 361 include Cu, Al, Ti and Au.

The reverse surface metal layer 360 and the bonding surface 210 of the heat dissipation member 200 are bonded together by solid state welding. In this embodiment, the bond promoting layer 361 is interposed between the reverse surface metal layer 360 and the bonding surface 210. As described above, the reverse surface 220 of the heat dissipation member 200 is irregular. This is as a result of pressing a jig against the reverse surface 220 in bonding the reverse surface metal layer 360 and the heat dissipation member 200 by solid state welding.

The sealing resin 400 covers the entirety of the semiconductor element 300 and the leads 101-107 except the terminal portions 120. The sealing resin 400 is made of an insulating material and made of e.g. black epoxy resin in this embodiment. In this embodiment, the sealing resin 400 also fills the space between the bonding surface 113 of the facing portion 110 and the bond promoting layer 335 of the electrode 330 at regions avoiding the projection 334.

In this embodiment, as described above, the heat dissipation member 200 and the reverse surface 320 of the semiconductor element 300 are solid-state welded. This allows bonding of the heat dissipation member 200 and the semi conductor element 300 to be performed more efficiently than in the case where these are bonded via e.g. a bonding material. Moreover, solid state welding enhances the efficiency of heat transfer from the semiconductor element 300 to the heat dissipation member 200, so that heat dissipation from the semiconductor element 300 is promoted.

In this embodiment again, the projection 334 and the facing portion 110 of the lead 101-107 are bonded to each other by solid state welding. As described above, solid state welding is the bonding by which two members are directly bonded to each other and does not require any bonding medium such as a wire or solder intervening between the two. Thus, solid state welding realizes higher bonding strength and higher bonding reliability. Moreover, the solid state welding can be performed collectively to all projections 334 and facing portions 110 of the leads 101-107, which leads to an enhancement in the manufacturing efficiency of the semiconductor device.

Owing to the provision of the projection 334, the bonding area between the electrode 330 and the facing portion 110 of the lead 101-107 is reduced. This leads to a reduction of the force that needs to be applied to achieve a predetermined bonding pressure in the solid state welding process. Thus, the semiconductor element 300 is prevented from being damaged by the bonding pressure. Moreover, owing to the provision of the projection 334, a space for loading the sealing resin 400 is defined between the functional surface 310 of the semiconductor element 300 and the bonding surface 113 of the facing portion 110 of the lead 101-107. Loading the sealing resin 400 in such a space assures that necessary insulation is reliably provided in the semiconductor device A4.

Arranging the projection 334 so as not to overlap the base layer 331 in plan view prevents an excessive force from being applied to a silicon member, which is the main body of the semiconductor element 300, in solid state welding. Moreover, since the projection 334 overlaps the passivation film 340 and the protective film 350 in plan view, the force applied during the solid state welding is absorbed by the passivation film 340 and the protective film 350.

Provision of the bond promoting layer 335 enhances the reliability of the solid state welding between the projection 334 and the facing portion 110.

FIGS. 24-26 show a semiconductor device according to a fifth embodiment of the present disclosure. The semiconductor device A5 of this embodiment includes a plurality of electroconductive support members 109, a semiconductor element 300, a sealing resin 400, an insulating layer 610 and a plating layer 620.

FIG. 24 is a front view showing the semiconductor device A5. FIG. 25 is a sectional view showing the semiconductor device A5. FIG. 26 is an enlarged sectional view showing a main section of the semiconductor device A5.

The plurality of electroconductive support members 109 form a conduction path between the semiconductor element 300 and outside of the semiconductor device A5 while supporting the semiconductor element 300. Each of the electroconductive support members 109 and the projection 334 of the corresponding electrode 330 are bonded together by solid state welding. Thus, as shown in FIG. 26, the semiconductor device A5 has a first solid-state welded portion 510 made up of part of the electroconductive support members 109 and part of the projection 334.

As shown in FIG. 26, each electroconductive support member 109 has a curved surface 115. The curved surface 115 surrounds the first solid-state welded portion 510.

Each electroconductive support member 109 is made of a metal and contains e.g. Cu as the main component. The electroconductive support member 109 may further contain Ni in addition to Cu. In this case, the proportion of Ni in the electroconductive support member 109 may be e.g. 8-12% by weight.

The sealing resin 400 covers the entirety of the semiconductor element 300 and the electroconductive support members 109. However, as shown in FIG. 24, the lower surface of each electroconductive support member 109 in FIG. 24 is exposed from the sealing resin 400.

The insulating layer 610 covers the lower surface in FIG. 25 of the sealing resin 400 and part of the lower surface in FIG. 25 of each electroconductive support member 109. The plating layer 620 is formed on part of the lower surface of the electroconductive support member 109 which is not covered by the insulating layer 610. The plating layer 620 is made of a metal such as Sn.

An example of a method of making the semiconductor device A5 is described below with reference to FIGS. 27-33.

First, a sacrificial member 150 is prepared as shown in FIG. 27. For example, the sacrificial member 150 is a plate-like member made of e.g. metal or resin. Then, a resist layer 151 is formed on the sacrificial member 150. The resist layer 151 is made of an insulating material and has a plurality of through-holes. Then, the electroconductive support members 109 are formed, by plating, in the through-holes of the resist layer 151. Each electroconductive support member 109 contains Cu as the main component. The electroconductive support member 109 may contain Ni in addition to Cu. In this case, the proportion of Ni in the electroconductive support member 109 may be e.g. 8-12% by weight.

Then, as shown in FIG. 28, the resist layer 151 is removed by e.g. etching. FIG. 29 is a sectional view of the electroconductive support member 109 obtained through the above-described process. As shown in the figure, in this state, the entire upper surface of the electroconductive support members 109 is convexly curved.

Then, as shown in FIG. 30, the sacrificial member 150 is placed on a jig 802. A semiconductor element 300 supported by a jig 803 is prepared. Specifically, the semiconductor element 300 is supported by the jig 803 with such a strength that allows the solid state welding described below to be performed. With a predetermined pressing force applied to the electroconductive support members 109 and the projections 334, the jig 803 is vibrated within the xy plane. The frequency of this vibration is lower than e.g. that of an ultrasonic wave and may be e.g. 100 Hz or less, or specifically, 50 to 60 Hz. Thus, the electroconductive support members 109 and the projections 334 are solid-state welded to provide the above-described first solid-state welded portion 510.

FIG. 31 is a sectional view showing the electroconductive support member 109 and the projection 334 which are solid-state welded. As shown in the figure, the portion of the upper surface of the electroconductive support member 109 which is pressed against the projection 334 is a fiat bonding surface 113, and the bonding surface 113 is surrounded by the curved surface 115.

Then, as shown in FIG. 32, the jig 802 and the jig 803 are removed, and sealing resin 400 is formed on the sacrificial member 150 by using e.g. a mold. The sealing resin 400 is formed so as to cover the semiconductor element 300 and part of each electroconductive support member 109.

Then, as shown in FIG. 33, the sacrificial member 150 is removed by e.g. etching. Thus, the lower surface in the figure of each eletroconductive support member 109 is exposed. Thereafter, the insulating layer 610 and the plating layer 620 are formed, whereby the above-described semiconductor device A5 is obtained.

This embodiment also enhances the manufacturing efficiency of the semiconductor device and realizes reliable bonding of the semiconductor element 300 and the electroconductive support members 100. In the solid state welding process, the electroconductive support members 105 are supported by the jig 802 via the sacrificial member 150. Thus, although traces corresponding to the shape of the jig 803 may be left on the sacrificial member 150, such traces cannot be left on the electroconductive support members 109. In this way, in is possible to prevent traces of the jig 802 from being left on the semiconductor device.

FIG. 34 illustrates another example of the electroconductive support member 109 of the semiconductor device A5. The electroconductive support member 109 of this example has an eave portion 116 adjacent to its upper surface. The eave portion 116 is formed by e.g. performing plating to a height above the resist layer 151 in the above-described manufacturing step for forming the electroconductive support members 109 in the through-holes of the resist layer 151 (FIG. 27).

FIG. 35 is a schematic enlarged sectional view showing the solid state welding of the electroconductive support member 109 of FIG. 34 and the projection 334. As shown in the figure, the portion of the upper surface of the electroconductive support member 109 which is pressed against the projection 334 is a flat bonding surface 113 and forms the first solid-state welded portion 510. The bonding surface 113 is surrounded by the curved surface 115. The save portion 116 extends in the direction in which the functional surface 310 of the semiconductor element 300 spreads.

FIG. 36 illustrates another example of the electroconductive support member 109 of the semiconductor device A5. The electroconductive support member 109 of this example has a bonding surface 113 which is entirely flat. The flat bonding surface 113 can be formed by removing part of the plating film by e.g. cutting, after the above-described plating process. This example assures that the solid state welding of the projection 334 and the electroconductive support member 109 is performed more reliably and quickly.

FIG. 37 illustrates another example of the electroconductive support member 109 of the semiconductor device A5. The electroconductive support member 109 of this example is provided with an oxide layer 140 that covers its entirety. The oxide layer 140 is formed by oxidizing the electroconductive support member 109 after the removing process shown in FIG. 36 is performed. In an example, when the electroconductive support member 109 contains Cu as the main component, the oxide layer 140 is made of CuO. The electroconductive support member 109 of this type can be formed by e.g. leaving the electroconductive support member 109 in an atmosphere of 50° C. for 24 hours. When the electroconductive support member 109 contains Ni in addition to Cu, the oxide layer 140 contains NiO in addition to CuO.

FIG. 38 is a schematic enlarged sectional view showing the solid state welding of the electroconductive support member 109 of FIG. 37 and the projection 334. As shown in the figure, the first solid-state welded portion 510 does not include the oxide layer 140. This is because the oxide layer 140 sandwiched between the projection 334 and the electroconductive support member 109 has been removed by applying vibration, with the projection 334 and the electroconductive support member 109 pressed against each other.

According to this example, the existence of the oxide layer 140 prevents premature solid state welding of the projection 334 and the electroconductive support member 109. That is, the projection 334 and the electroconductive support member 109 are prevented from bonding to each other in an improper positional relationship at an unduly early stage as the projection 334 and the electroconductive support member 109 are pressed against each other and vibration is applied in the solid state welding process.

The semiconductor device according to the present disclosure is not limited to the foregoing embodiments. The specific structure of each part of the semiconductor device according to the present disclosure can be varied in design in many ways.

1. A semiconductor device comprising:
a semiconductor element including a functional surface formed with a functional circuit and a reverse surface opposite to the functional surface;
an electroconductive support member supporting the semiconductor element and electrically connected to the semiconductor element; and
a resin package covering the semiconductor element and at least a part of the electroconductive support member,
wherein the semiconductor element is provided with an electrode including a projection formed on the functional surface and a reinforcing layer formed on the functional surface, and
the semiconductor device further comprises a first solid-state welded portion formed by solid state welding of at least a part of the projection of the electrode and at least a part of the electroconductive support member.

2. The semiconductor device according to claim 1, wherein the electrode includes a base layer in contact with the functional surface.

3. The semiconductor device according to claim 2, wherein the base layer is made of Al.

4. The semiconductor device according to claim 2, wherein the projection and the base layer do not overlap with each other in plan view.

5. The semiconductor device according to claim 2, wherein the electrode includes a foundation layer formed on the base layer.

6. The semiconductor device according to claim 5, wherein the foundation layer is made of one of Ti, W or Ta.

7. The semiconductor device according to claim 5, wherein the electrode includes a re-distribution layer formed on the foundation layer, and
the projection is formed on the re-distribution layer.

8. The semiconductor device according to claim 7, wherein the re-distribution layer is made of Cu.

9. The semiconductor device according to claim 7, wherein the re-distribution layer is larger than the base layer in plan view.

10. The semiconductor device according to claim 7, wherein the reinforcing layer is provided between the re-distribution layer and the projection.

11. The semiconductor device according to claim 10, wherein the reinforcing layer includes a first electroconductive layer.

12. The semiconductor device according to claim 11, wherein the first electroconductive layer is made of Ni.

13. The semiconductor device according to claim 11, wherein the reinforcing layer includes a second electroconductive layer formed on the first electroconductive layer and closer to the projection than is the first electroconductive layer.

14. The semiconductor device according to claim 13, wherein the second electroconductive layer is made of Ti.

15. The semiconductor device according to claim 13, wherein the reinforcing layer comprises a third electroconductive layer formed on the second electroconductive layer and closer to the projection than is the second electroconductive layer.

16. The semiconductor device according to claim 15, wherein the third electroconductive layer is made of Cu.

17. The semiconductor device according to claim 5, wherein the reinforcing layer includes an insulating layer made of an insulating material, and
the electrode includes a re-distribution layer formed opposite to the functional surface with respect to the insulating layer.

18. The semiconductor device according to claim 17, wherein the insulating layer is formed with a through-hole that receives the projection.

19. The semiconductor device according to claim 17, wherein the insulating layer is made of polyimide.

20. The semiconductor device according to claim 7, wherein the electrode includes a bond promoting layer as an outermost layer.

21. The semiconductor device according to claim 20, wherein the bond promoting layer contains at least one of Ni or Pd.

22. The semiconductor device according to claim 21, wherein the bond promoting layer comprises a Ni layer formed on the projection and a Pd layer formed on the Ni layer.

23. The semiconductor device according to claim 7, further comprising a passivation film covering the functional surface and formed with a thorough-hole that allows the electrode to be in contact with the functional surface.

24. The semiconductor device according to claim 23, wherein the passivation film is made of SiN.

25. The semiconductor device according to claim 25, wherein the re-distribution layer overlaps with the passivation film in plan view.

26. The semiconductor device according to claim 23, wherein the projection overlaps with the passivation film in plan view.

27. The semiconductor device according to claim 23, further comprising a protective film formed on the passivation film.

28. The semiconductor device according to claim 27, wherein the protective film is made of polyimide.

29. The semiconductor device according to claim 27, wherein the re-distribution layer overlaps with the protective film in plan view.

30. The semiconductor device according to claim 27, wherein the projection overlaps with the protective film in plan view.

31. The semiconductor device according to claim 1, wherein the projection is made of Cu.

32. The semiconductor device according to claim 1, wherein the electroconductive support member comprises a lead made of metal.

33. The semiconductor device according to claim 32, wherein a part of the lead projects from the resin package.

34. The semiconductor device according to claim 32, wherein the lead includes an irregular surface opposite to the first solid-state welded portion.

35. The semiconductor device according to claim 1, wherein the semiconductor element is provided with a plurality of electrodes.

36. The semiconductor device according to claim 1, wherein the electrode includes a plurality of projections.

37. The semiconductor device according to claim 1, further comprising a heat dissipation member bonded to the semiconductor element,
wherein the semiconductor element is further provided with a reverse surface metal layer formed on the reverse surface, and
the semiconductor device further comprises a second solid-state welded portion formed by solid state welding of at least a part of the reverse surface metal layer and at least a part of the heat dissipation member.

38. The semiconductor device according to claim 37, wherein the reverse surface metal layer is formed with a bond promoting layer.

39. The semiconductor device according to claim 38, wherein the bond promoting layer of the reverse surface metal layer contains at least one of Ni or Pd.

40. The semiconductor device according to claim 37, wherein the heat dissipation member is formed with a bond promoting layer.

41. The semiconductor device according to claim 40, wherein the bond promoting layer of the heat dissipation member contains at least one of Ni or Pd.

42. The semiconductor device according to claim 37, wherein the heat dissipation member includes an irregular surface opposite to the second solid-state welded portion.

43. The semiconductor device according to claim 37, wherein the heat dissipation member includes a surface that is opposite to the second solid-state welded portion and exposed outside the resin package.

44. The semiconductor device according to claim 1, wherein the electroconductive support member includes a projection extending toward the semiconductor element.

45. The semiconductor device according to claim 1, wherein an entirety of the electroconductive support member projects toward the semiconductor element.

46. The semiconductor device according to claim 45, wherein the electroconductive support member includes a curved surface surrounding the first solid-state welded portion.

47. The semiconductor device according to claim 46, wherein the electroconductive support member includes an eave portion extending away from the first solid-state welded portion in a direction in which the functional surface spreads.

48. The semiconductor device according to claim 45, wherein the electroconductive support member includes an oxide layer formed in a region avoiding the first solid-state welded portion.

49. The semiconductor device according to claim 45, wherein the electroconductive support member contains Cu as a main component thereof.

50. The semiconductor device according to claim 49, wherein the electroconductive support member further contains Ni.

51. A method of making a semiconductor device, the method comprising:
a step of forming an electroconductive support member of a metal on a sacrificial member;
a solid state welding step of bonding, by solid state welding, the electroconductive support member and an electrode formed on a functional surface of a semiconductor element and including a projection, and
a step of removing the sacrificial member.

52. The method according to claim 51, further comprising the step of covering the semiconductor element and at least a part of the electroconductive support member with a sealing resin after the solid state welding step and before the step of removing the sacrificial member.

53. The method according to claim 52, wherein the step of forming the electroconductive support member comprises forming, on a part of the sacrificial member, a resist layer including a through-hole, and metal plating a part of the sacrificial member which is exposed through the resist layer.

54. The method according to claim 53, further comprising the step of, after the step of forming the electroconductive member and before the solid state welding step, forming a flat surface on the electroconductive support member by removing a part of the electroconductive support member that is spaced apart from the sacrificial member.

55. The method according to claim 53, wherein the electroconductive support member contains Cu as a main component thereof.

56. The method according to claim 55, wherein the electroconductive support member further contains Ni.

57. The method according to claim 53, further comprising the step of oxidizing the electroconductive support member to form an oxide layer after the step of forming the flat surface and before the solid state welding step.
